(19) United States
(12) Patent Application Publication
(10) Pub. No.: US 2011/0304041 A1
(43) Pub. Date: Dec. 15, 2011

(54) ELECTRICALLY CONNECTING ROUTES OF SEMICONDUCTOR CHIP PACKAGE CONSOLIDATED IN DIE-ATTACHMENT

(76) Inventor: Chi-Yuan CHUNG, Hukon Shiang (TW)

(21) Appl. No.: 12/831,578

(22) Filed: Jul. 7, 2010

(30) Foreign Application Priority Data
Jun. 15, 2010 (TW) 099119586

(51) Int. Cl. H01L 23/498

(52) U.S. Cl. 257/737; 257/E23.068

(57) ABSTRACT

A chip package comprises a chip, a plurality of bumps, and a die-attaching tape where the bumps are jointed to the corresponding bonding pads on the active surface of the chip. The die-attaching tape consists of a wiring core, a first dielectric adhesive, and a second dielectric adhesive where the wiring core is sandwiched between the first dielectric adhesive and the second dielectric adhesive. The wiring core is of a thickness of a dielectric material and includes a plurality of conductive traces separated by the dielectric material. The conductive traces are also of the thickness of the dielectric material. The die-attaching tape is attached to the active surface of the chip by the first dielectric adhesive to make the bumps penetrate the first dielectric adhesive and joint to the corresponding conductive traces. Therefore, the die-attaching tape can have both functions of holding the chip and transversely transmitting signals to substrate or another chip to eliminate or reduce the conventional wire-bonding processes.

### FIELD OF THE INVENTION

The present invention relates to semiconductor devices with die-attaching mechanism, especially to semiconductor chip packages implementing special die-attaching tapes to eliminate or reduce bonding wires.

### BACKGROUND OF THE INVENTION

In the existing semiconductor packaging processes, back surfaces of chips are attached to substrates by disposing solid die-attaching films or liquid die-attaching pastes on the substrates followed by wire-bonding processes to complete electrical signal interconnections between the chips and the substrates. In one conventional semiconductor package using bonding wires, a chip is face-up disposed on top of a substrate, what is followed is electrical connection of the bonding pads of a chip to the bonding fingers of a substrate by bonding wires formed by wire bonding processes and then an encapsulant is formed by molding to encapsulate the chip for assembling an IC chip package. Various wire-bonding defeats may occur more seriously when the encapsulant of the IC package becomes thinner and thinner or when more chips are stacked in a package, such as breaking of bonding wires at the bending portions, limited minimum loop heights, wire sweep, etc. Furthermore, bonding wires formed by wire-bonding processes are responsible for all of electrical connections between chips and substrates but not for heat conduction nor chip attachment and the encapsulant encapsulating a chip is well known for poor heat conduction leading to heat dissipation issues of the top chip in multi-chip packages.

### SUMMARY OF THE INVENTION

The main purpose of the present invention is to provide a chip package to solve the problems mentioned above. Conventional wire-bonding defeats in a chip package can be avoided or lessened. The heat dissipation from chip to substrate can be enhanced.

The second purpose of the present invention is to provide a chip package without bonding wires as well as without loop heights formed by wire bonding processes to save the cost of gold wires.

The third purpose of the present invention is to provide a chip package to reduce overall package thicknesses to enhance the dimension shrinkage of a chip package as well as to stack multiple chips in a thinner package.

According to the present invention, a chip package is revealed comprising a first chip, a plurality of first bumps, and a die-attaching tape. The first chip has a first active surface, an opposing first back surface and a plurality of first bonding pads disposed on the first active surface. The first bumps are jointed onto the first bonding pads and the die-attaching tape is attached to the first active surface of the first chip. The die-attaching tape consists of a first dielectric adhesive, a second dielectric adhesive and a wiring core sandwiched between the first dielectric adhesive and the second dielectric adhesive, wherein the wiring core is of a thickness of a dielectric material and includes a plurality of conductive traces separated by the dielectric material, wherein the conductive traces are also of the thickness of the dielectric material. Furthermore, the first dielectric adhesive is adhered to the first active surface with the first bumps penetrating through the first dielectric adhesive and jointing to the corresponding conductive traces.

The chip package according to the present invention has the following advantages or effects:
1. Through the implementation of the die-attaching tape with the functions of firmly holding a chip as well as transmitting signals as a technical mean, not only wire bonding defeats in a wire-bonding chip package can be avoided but also heat dissipation from the chip to the substrate can further be enhanced.
2. Through the implementation of the die-attaching tape with the functions of firmly holding a chip as well as transmitting signals as a technical mean, there is no bonding wire as well as no loop height formed by wire bonding processes to save the cost of gold wires.
3. Through the implementation of the die-attaching tape with the functions of firmly holding a chip as well as transmitting signals as a technical mean, the overall package thicknesses can further be reduced to enhance the dimension shrinkage of a chip package or to stack multiple chips in a thinner package.

### DESCRIPTION OF THE DRAWINGS

FIG. 1 is a cross-sectional view of a chip package according to the first embodiment of the present invention.

FIG. 2 is a three-dimensional exploded view of the chip package before molding according to the first embodiment of the present invention.

FIGS. 3A to 3B are cross-sectional views parallel to and perpendicular to the die-attaching tape implemented in the chip package according to the first embodiment of the present invention.

FIG. 4 is a three-dimensional view of the die-attaching tape rolled up as a roll before packaging according to the first embodiment of the present invention.

FIG. 5 is a cross-sectional view of another chip package according to the second embodiment of the present invention.

FIG. 6 is a cross-sectional view of the chip package illustrating a first chip bonded on a second chip through the die-attaching tape according to the second embodiment of the present invention.

FIG. 7 is a partial cross-sectional view of another chip package according to the third embodiment of the present invention.

FIG. 8 is a three-dimensional exploded view of the chip package before molding according to the third embodiment of the present invention.

### DETAILED DESCRIPTION OF THE INVENTION

With reference to the attached drawings, the present invention is described by means of the embodiment(s) below where the attached drawings are simplified for illustration purposes only to illustrate the structures or methods of the present invention by describing the relationships between the components and assembly in the present invention. Therefore, the components shown in the figures are not expressed with the actual numbers, actual shapes, actual dimensions, nor with the actual ratio. Some of the dimensions or dimension ratios have been enlarged or simplified to provide a better illustration. The actual numbers, actual shapes, or actual dimension ratios can be selectively designed and disposed and the detail component layouts may be more complicated.

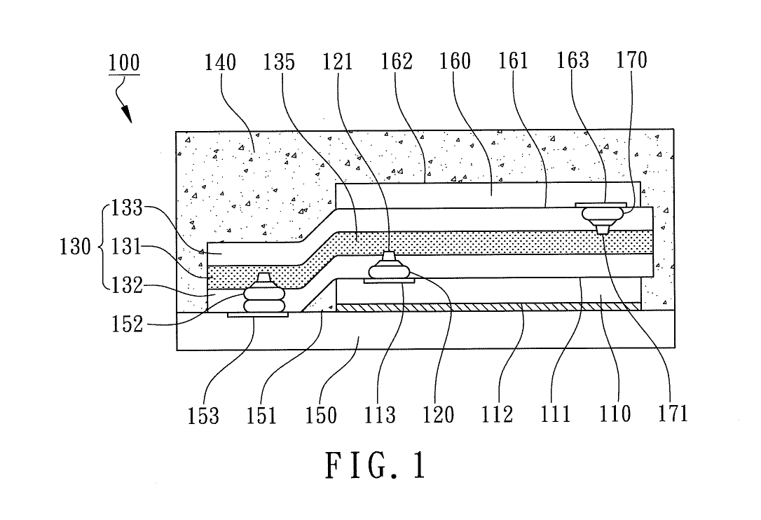

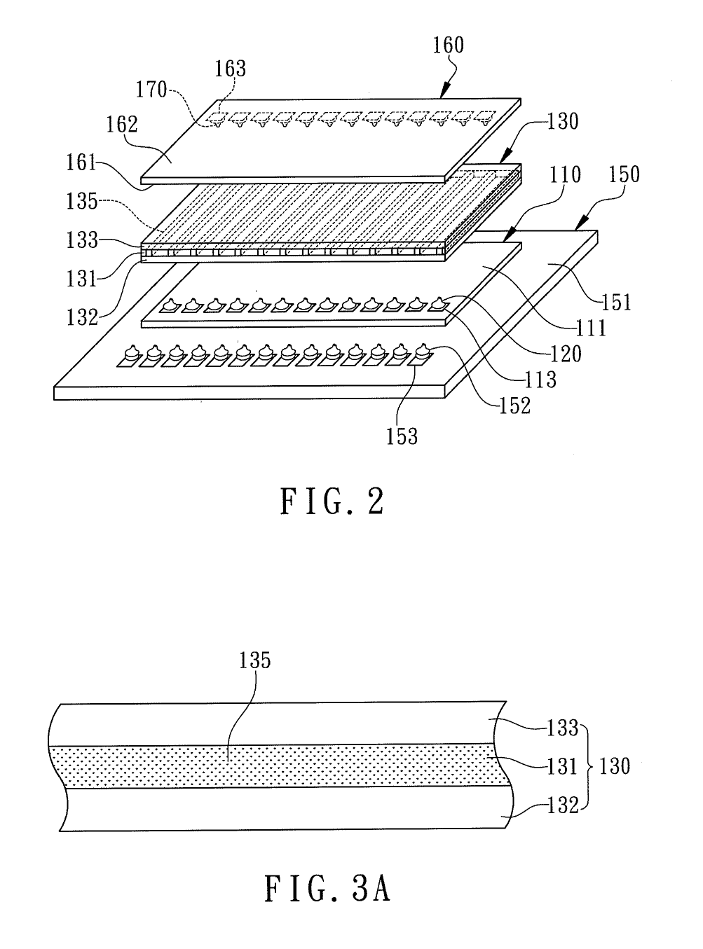

According to the preferred embodiment of the present invention, a chip package is illustrated in FIG. 1 for a cross-sectional view and in FIG. 2 for a three-dimensional exploded view before molding. The chip package 100 primarily comprises a first chip 110, a plurality of first bumps 120, and a die-attaching tape 130.

The first chip 110 is an IC (integrated circuit) semiconductor component, which has a first active surface 111, an opposing first back surface 112 and a plurality of first bonding pads 113 disposed on the first active surface 111. The material of the first chip 110 can be Si, GaAs, or other semiconductor materials. The IC circuitry of the first chip 110 is formed on the first active surface 111 where the first bonding pads 113 are the external terminals of the IC circuitry. The material of the first bonding pads 113 is aluminum (Al) or copper (Cu). Normally, the first bonding pads 113 are disposed at one single side or at the center of the first active surface 111. In the present embodiment, as shown in FIG. 1 again, the first bonding pads 113 are disposed on one single side of the first active surface 111 which are normally seen on flash memory. The first chip 110 can be configured for disposing on a substrate or on another chip. In the present embodiment, the first active surface 111 of the first chip 110 is facedown disposed on a substrate 150.

The first bumps 120 are jointed onto the corresponding first bonding pads 113 where the first bumps 120 can be pillar conductive bumps. The joint is formed by metal to metal bonding relationship between two elements. In one embodiment, the first bumps 120 can be copper pillar bumps with a higher melting point which can not deform under chip-attaching temperature to enable the first bumps 120 to penetrate through the dielectric adhesive of the die-attaching tape 130 where the copper pillars can be formed by electroplating.

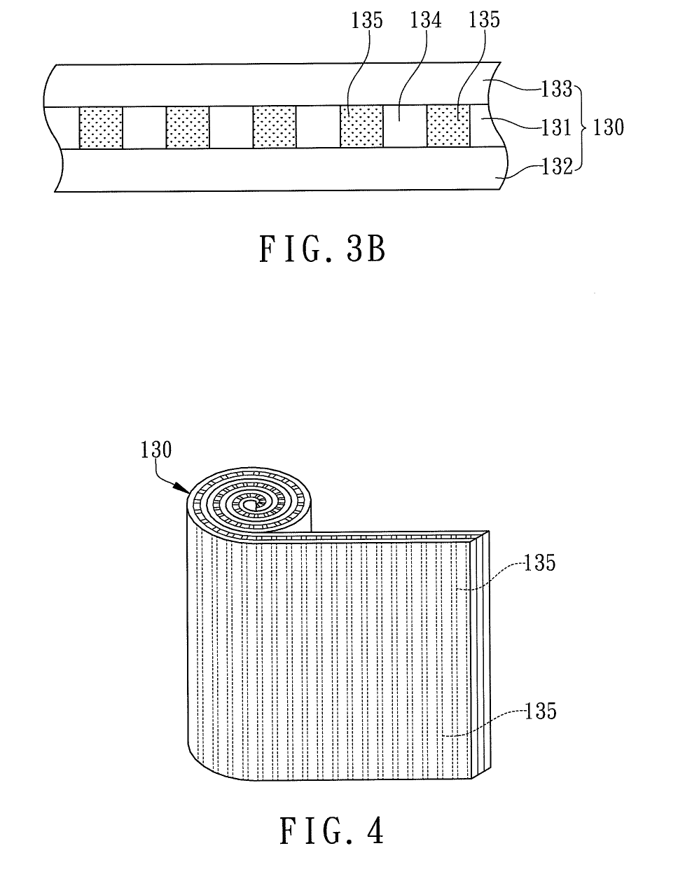

As shown in FIG. 1 again, the die-attaching tape 130 is attached to the first active surface 111 of the first chip 110 to make electrical connection as well as heat dissipation corresponding to the first bumps 120. To be more specific, as shown in FIG. 3A and FIG. 3B, the die-attaching tape 130 consists of a wiring core 131, a first dielectric adhesive 132, and a second dielectric adhesive 133 where the wiring core 131 is sandwiched between the first dielectric adhesive 132 and the second dielectric adhesive 133. Additionally, the wiring core 131 is of a thickness of a dielectric material 134 and includes a plurality of conductive traces 135 separated by the dielectric material 134, wherein the conductive traces 135 are also of the thickness of the dielectric material 134. The thickness of the dielectric material 134 might range from 8 um to 50 um. The conductive traces 135 are disposed in uniform interval and are electrically isolated to each other by the dielectric material 134, therefore, the whole wiring core 131 is a single-layer structure, not a PCB nor an anisotropic conductive layer nor an ACF film. As shown in FIG. 1, the first dielectric adhesive 132 is adhered to the first active surface 111 of the first chip 110 with the first bumps 120 penetrating through the first dielectric adhesive 132 and jointing to the corresponding conductive traces 135 to form electrical connections but without penetrating through the conductive traces 135. The spacing between the conductive traces 135 may be not less than the width of the conductive traces 135 and not greater than the spacing between the first bumps 120 or the spacing between the first bonding pads 113. The total volume of the conductive traces 135 occupies 30˜60% of the volume of the wiring core 131 so that the conductive traces 135 not only electrically connect the first bumps 120 on the first chip 110 but also effectively dissipate the heat generated from the first chip 110. The thickness of the wiring core 131 can be equal or less than the thickness of either the first dielectric adhesive 132 or the second dielectric adhesive 133. The thickness of each of the first dielectric adhesive 132 and the second dielectric adhesive 133 ranges from 8 um to 50 um. As shown in FIG. 4, the die-attaching tape 130 can be rolled up as a roll for easy storage.

To be more specific, the materials of the first dielectric adhesive 132 and the second dielectric adhesive 133 can be the same such as adhesive polyimide layers with the functions of electrical isolation as well as adhesion. The first dielectric adhesive 132 and the second dielectric adhesive 133 are disposed on the top surface and on the bottom surface of the wiring core 131, respectively, which can be thermosetting or thermoplastic made of the dielectric materials with adhesion such as epoxy, B-stage paste, or organic resin. Preferably, the first dielectric adhesive 132 and the second dielectric adhesive 133 contain resins with the characteristic of multiple curing stages. These dielectric adhesives 132 and 133 are pre-cured in tape manufacturing processes so that these dielectric adhesives 132 and 133 are in an intermediate cured state (or called B-stage). Each of these dielectric adhesives 132 and 133 has a glass transition temperature (Tg) close to and below the chip-attaching temperature to transform solid to fluid or colloid to make the bumps easily penetrate through these dielectric adhesives. Preferably, the glass transition temperature (Tg) of the first dielectric adhesive 132 is greater than the Tg of the second dielectric adhesive 133. When attaching to the first chip 110, the first dielectric adhesive 132 can become soft and fluid by raising temperatures higher than its Tg so that the first bumps 120 can easily penetrate through the first dielectric adhesive 132 and joint to the corresponding conductive traces 135 to complete electrical connections. When the second dielectric adhesive 133 is adhered to other components, the first dielectric adhesive 132 can become more solid or viscous and less fluid to firmly hold the first bumps 120. To be described in detail, the conductive traces 135 are conductive metals formed by electroplating where the materials can be copper, iron, or aluminum. For further description, as shown in FIG. 2, the conductive traces 135 can be parallel straight lines and the orientation of the conductive traces 135 is perpendicular to the orientation of the first bonding pads 113. Each first bonding pad 113 is electrically connected to at least one conductive trace 135. The conductive traces 135 do not need different designs according to different chip dimensions as long as the pitch between the first bonding pads 113 is equal to the pitch of the conductive traces 135. Alternately, the pitch of the first bonding pads 113 is integral multiples of the pitch of the conductive traces 135 so that at least half of the conductive traces 135 are not connected with the first bonding pads 113. The unconnected conductive traces 135 can be configured to enhance heat dissipation from the first chip 110 to the substrate. For example, the pitch of the first bonding pad 113 is 20 um, the pitch of the conductive traces 135 can be 20 um or 10 um.

Preferably, the first bumps 120 are stud bumps formed by wire bonding processes with extruded wire tips 121 to be embedded into the conductive traces 135 to further ensure that the first bumps 120 electrically connect the first bonding pads 113 to the corresponding conductive traces 135. Each first bump 120 can be formed by firstly forming a gold ball at the front end of a gold wire at a conventional capillary through high voltage (around 4,000 volts) followed by breaking the bonding wire to form a stud bump.

As shown in FIG. 1 and FIG. 2, in the present embodiment, the chip package 100 further comprises a substrate 150 and a plurality of substrate bumps 152. The substrate 150 can be a printed circuit board with multi-layer circuitry such as PCB, ceramic substrate, circuitry film, or pre-molded leadframe to be a chip carrier for electrical connection and transmission. The substrate 150 has a top surface 151 and a corresponding bottom surface where a plurality of bonding fingers 153 are disposed on the top surface 151. The substrate bumps 152 are disposed on the bonding fingers 153. In the present embodiment, the substrate bumps 152 are formed by stacking a plurality of stud bumps to achieve higher bump heights. The first chip 110 can be attached to the substrate 150 by a conventional die-attaching material. The die-attaching tape 130 is extended from the first chip 110 and is further attached to the top surface 151 of the substrate 150 to make the first dielectric adhesive 132 adhere to the substrate 150 with the substrate bumps 152 penetrating through the first dielectric adhesive 132 and jointing to the corresponding conductive traces 135. Therefore, the first chip 110 can be electrically connected to the substrate 150 through the conductive traces 135 of the wiring core 131 without bonding wires as well as without loop heights formed by wire bonding processes to effectively prevent breaking of bonding wires, exposure of bonding wires from an encapsulant, sweeping of bonding wires, to save the cost of gold wires and to further enhance heat dissipation from the first chip 100 to the substrate 150. Furthermore, the chip package 100 can further be implemented in thinner packages for stacking multiple dice.

In the present embodiment, as shown in FIG. 1, the chip package 100 further comprises a second chip 160 and a plurality of second bumps 170. The second chip 160 is disposed on the first chip 110 by the die-attaching tape 130. The second chip 160 has a second active surface 161 and a corresponding second back surface 162 where a plurality of second bonding pads 163 are disposed on the second active surface 161. The second chip 160 can be the same chip as the first chip 110 with the same dimension, function, and structure except for the arrangement of the second bonding pads 163. The second bumps 170 are jointed to the second bonding pads 163. Moreover, in the present embodiment, the second chip 160 and the first chip 110 are face-to-face stacked together by implementing the die-attaching tape 130 to completely fill the gap between the first active surface 111 of the first chip 110 and the second active surface 161 of the second chip 160. To be described in detail, as shown in FIG. 2, the second active surface 161 of the second chip 160 is face-down attached to the second dielectric adhesive 133 of the die-attaching tape 130 with the second chip 160 aligned to the first chip 110 by jointing the second bumps 170 to the corresponding conductive traces 135 without aligning to the first bumps 120.

To be more specific, as shown in FIG. 1, the second dielectric adhesive 133 is adhered to the second active surface 151 where the second bumps 170 penetrate through the second dielectric adhesive 133 and joint to the corresponding conductive traces 135. In the present embodiment, the second bumps 170 can be stud bumps formed by wire-bonding processes as the first bumps 120 with extruded wire tips 171 which can be embedded into the conductive traces 135 so that the electrical connections between the first chip 110 and the second chip 160 are formed through the conductive traces 135.

Therefore, the first dielectric adhesive 132 and the second dielectric adhesive 133 used as the bottom and the top of the die-attaching tape 130 are implemented to firmly hold and adhere the first chip 110 and the second chip 160, moreover, the conductive traces 135 of the wiring core 131 are then implemented to complete electrical connections to make the die-attaching tape 130 having multiple functions including holding chips, transmitting electrical signals and heat dissipation.

As shown in FIG. 1, the chip package 100 further comprises an encapsulant 140 encapsulating the first chip 110 and the die-attaching tape 130. In the present embodiment, the encapsulant 140 is formed over the top surface 151 of the substrate 150 and the second chip 160 is also encapsulated by the encapsulant 140 to provide appropriate packaging protection to avoid electrical short and particle contamination. In the present embodiment, the encapsulant 140 is an Epoxy Molding Compound (EMC) to form on the substrate 150 by transfer molding processes.

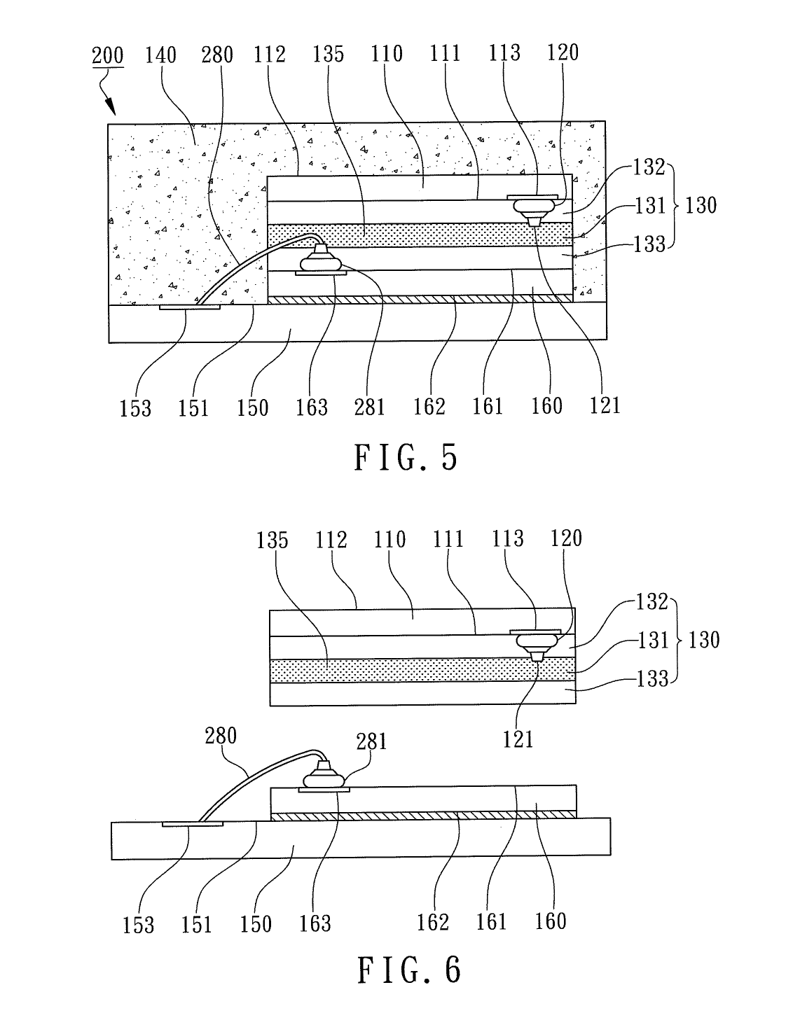

According to the second embodiment of the present invention, another chip package is illustrated in FIG. 5 for a cross-sectional view and FIG. 6 a cross-sectional view illustrating a first chip 110 bonded on a second chip 120 through the die-attaching tape 130. The described names and numbers of the major components of the chip package 200 with the same functions will be the same as in the first embodiment which will not be described again.

In the present embodiment, the die-attaching tape 130 does not extend over the first active surface 111 of the first chip 110 where the die-attaching tape 130 can be attached to the first chip 110 in wafer-level processes. Moreover, the chip package 200 further comprises a substrate 150, a second chip 160, and a plurality of bonding wires 280 where the second back surface 162 of the second chip 160 is disposed on the substrate 150. The bonding wires 280 electrically connect the second bonding pads 163 of the second chip 160 to the bonding fingers 153 of the substrate 150 where a plurality of ball bonds 281 of the bonding wires 280 are jointed to the second bonding pads 163. The second chip 160 and the first chip 110 are face-to-face stacked together where the second dielectric adhesive 133 is adhered to the second active surface 161 with the ball bonds 281 of the bonding wires 280 penetrating through the second dielectric adhesive 133 and jointing to the corresponding conductive traces 135.

To be more specific, as shown in FIG. 6, the bonding wires 280 are formed by wire-bonding processes which are made of gold or copper where both terminals of the bonding wires 280 are formed by ultrasonic bonding, thermal compression, or thermosonic to electrically connect the second chip 160 to the substrate 150. Preferably, the bonding wires 280 are copper wires to be stiff for easily penetrating through the second dielectric adhesive 133. In the present embodiment, the ball bonds 281 (alias first bonds) of the bonding wires 280 are formed on the second bonding pads 163. The wedge bonds (alias second bonds) of the bonding wires 280 are formed on the bonding fingers 153. When stacking chips, the die-attaching tape 130 can be preformed on the first active surface 111 of the first chip 110 to make electrical connections between the first bumps 120 and the conductive traces 135 followed by facedown attaching the first active surface 111 of the first chip 110 to the second active surface 161 of the second chip 160 under an appropriate temperature with ultrasonic, thermal compression, or combination of both to make the ball bumps 281 of the bonding wires 280 penetrating through the second dielectric adhesive 133 and jointing to the corresponding conductive trace 135 to electrically connect the first chip 110 to the second chip 160 as well as to the substrate 150. Therefore, the numbers of the bonding wires and the penetrating bumps required in the IC package can be reduced where the heat dissipation between the first chip 110 and the second chip 160 can be further enhanced without loop heights over the top chip which is most suitable for stacking multiple chips in a thinner package.

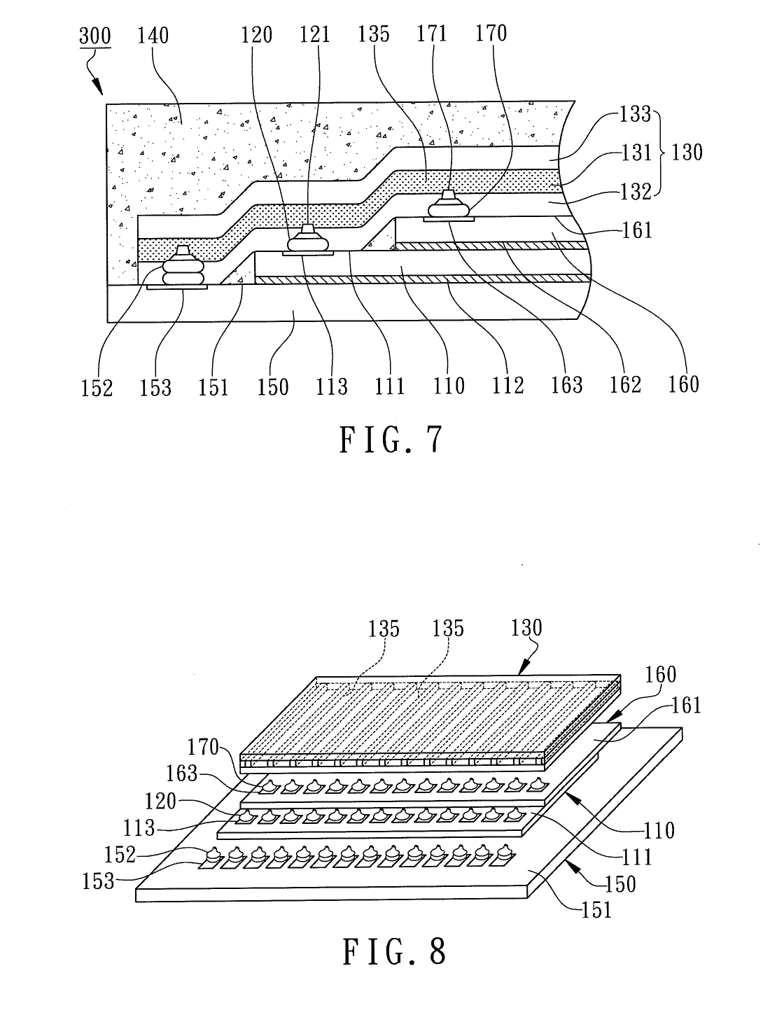

In the third embodiment of the present invention, another chip package is illustrated in FIG. 7 for a partial cross-sectional view and in FIG. 8 for a three-dimensional exploded view before molding. The chip package 300 primarily comprises a first chip 110, a plurality of first bumps 120, and a die-attaching tape 130 where the described names and numbers of the major components with the same functions will be the same as in the first embodiment which will not be described again. The purpose is to illustrate the implementation of the different thin packages for stacking more chips. In the present embodiment, the first chip 110 is disposed on the substrate 150 and a plurality of substrate bumps 152 are jointed on the corresponding bonding fingers 153 of the substrate 150. The die-attaching tape 130 is extended from the first chip 110 and is further attached to the top surface 151 of the substrate 150 to make the first dielectric adhesive 132 adhere to the substrate 150 with the substrate bumps 152 penetrating through the first dielectric adhesive 132 and jointing to the corresponding conductive traces 135.

In the present embodiment, the chip package 300 further comprises at least a second chip 160 and a plurality of second bumps 170 where the second chip 160 and the first chip 170 are stair-like stacked together. The second back surface 162 of the second chip 160 is stacked on the first active surface 111 of the first chip 110 without fully covering the first active surface 111 to expose the first bumps 120. In a different embodiment, more chips can be stacked on top of the second chip 160 to achieve more memory capacities or more expanded functions.

Two sides of the die-attaching tape 130 are extended over the first active surface 111 of the first chip 110 where the first dielectric adhesive 132 is adhered to the second active surface 161 with the second bumps 170 penetrating through the first dielectric adhesive 132 and jointing to the corresponding traces 135. The conductive traces 135 are downwardly extended from the horizontal plane of the second bumps 170 and electrically connected to the corresponding first bumps 120. Then, the conductive traces 135 are further downwardly extended from the horizontal plane of the first bumps 112 and bonded to the corresponding substrate bumps 152 to make a thin package without loop heights to further reduce the overall package thickness to effectively shrink the dimension of the chip package 300 to stack more chips.

As shown in FIG. 8, when stacking multiple chips, the die-attaching tape 130 is attached to the active surface 111 of the first chip 110 and the active surface 161 of the second chip 160 with both active surfaces face-up using thermal-compression under an appropriate temperature, meanwhile, the first bumps 120, the second bumps 170, and the substrate bumps 152 can penetrate through the first dielectric adhesive 132 and joint to the corresponding conductive traces 135 to electrically connect the first chip 110 and the second chip 160 to the substrate 150. The conductive traces 135 can replace the conventional bonding wires formed by wire-bonding processes to resolve the conventional wire-bonding defeats such as easy breaking at the bending of bonding wires, limited minimum loop heights, wire sweep, higher cost of gold wires, etc.

The above description of embodiments of this invention is intended to be illustrative but not limited. Other embodiments of this invention will be obvious to those skilled in the art in view of the above disclosure which still will be covered by and within the scope of the present invention even with any modifications, equivalent variations, and adaptations.

What is claimed is:

1. A chip package comprising:
a first chip having a first active surface, an opposing first back surface and a plurality of first bonding pads disposed on the first active surface;
a plurality of first bumps jointed onto the first bonding pads; and
a die-attaching tape attached to the first active surface of the first chip, the die-attaching tape consisting of a first dielectric adhesive, a second dielectric adhesive and a wiring core sandwiched between the first dielectric adhesive and the second dielectric adhesive, wherein the wiring core is of a thickness of a dielectric material and includes a plurality of conductive traces separated by the dielectric material, wherein the conductive traces are also of the thickness of the dielectric material;
wherein the first dielectric adhesive is adhered to the first active surface with the first bumps penetrating through the first dielectric adhesive and jointing to the corresponding conductive traces.

2. The chip package as claimed in claim 1, wherein the conductive traces are parallel straight lines and the orientation of the conductive traces is perpendicular to the orientation of the first bonding pads.

3. The chip package as claimed in claim 1, wherein the first bumps are stud bumps formed by wire-bonding processes with extruded wire tips to be embedded into the conductive traces.

4. The chip package as claimed in claim 1, further comprising an encapsulant encapsulating the first chip and the die-attaching tape.

5. The chip package as claimed in claim 1, further comprising a substrate and a plurality of substrate bumps disposed on a plurality of bonding fingers on the substrate, wherein the first chip are disposed on the substrate and the die-attaching tape is extended from the first chip and is further attached to the substrate to make the first dielectric adhesive adhere to the substrate with the substrate bumps penetrating through the first dielectric adhesive and jointing to the corresponding conductive traces.

6. The chip package as claimed in claim 5, further comprising:
a second chip having a second active surface, an opposing second back surface and a plurality of second bonding pads disposed on the second active surface; and
a plurality of second bumps jointed onto the second bonding pads;
wherein the first chip and the second chip are face-to-face stacked together so that the second dielectric adhesive is adhered to the second active surface with the second bumps penetrating through the second dielectric adhesive and jointing to the corresponding conductive traces.

7. The chip package as claimed in claim 5, further comprising:
a second chip having a second active surface, an opposing second back surface and a plurality of second bonding pads disposed on the second active surface; and
a plurality of second bumps jointed onto the second bonding pads;
wherein the first chip and the second chip are stair-like stacked together so that two sides of the die-attaching tape are extended over the first active surface of the first chip to make the first dielectric adhesive adhere to the second active surface with the second bumps penetrating through the first dielectric adhesive and jointing to the corresponding conductive traces.

8. The chip package as claimed in claim 1, wherein the die-attaching tape does not extend over the first active surface of the first chip.

9. The chip package as claimed in claim 8, further comprising:
a substrate having a plurality of bonding fingers;
a second chip having a second active surface, an opposing second back surface and a plurality of second bonding pads disposed on the second active surface, wherein the second back surface of the second chip is attached onto the substrate; and
a plurality of bonding wires connecting the second bonding pads to the bonding fingers with a plurality of ball bonds of the bonding wires jointed onto the second bonding pads;
wherein the first chip and the second chip are face-to-face stacked together so that the second dielectric adhesive adheres to the second active surface with the ball bonds of the bonding wires penetrating through the second dielectric adhesive and jointing to the corresponding conductive traces.

10. The chip package as claimed in claim 9, wherein the bonding wires are copper wires.

11. The chip package as claimed in claim 1, wherein the pitch of the first bonding pads is equal to the pitch of the conductive traces.

12. The chip package as claimed in claim 1, wherein the pitch of the first bonding pads is integral multiples of the pitch of the conductive traces so that at least half of the conductive traces are not connected with the first bonding pads.

13. The chip package as claimed in claim 1, wherein the first dielectric adhesive and the second dielectric adhesive are resins with the characteristic of multiple curing stages.

14. The chip package as claimed in claim 13, wherein the Tg of the first dielectric adhesive is greater than the Tg of the second dielectric adhesive.
